(19) United States
(12) Patent Application Publication
(10) Pub. No.: US 2010/0264522 A1
(43) Pub. Date: Oct. 21, 2010

(54) SEMICONDUCTOR DEVICE HAVING AT LEAST ONE BUMP WITHOUT OVERLAPPING SPECIFIC PAD OR DIRECTLY CONTACTING SPECIFIC PAD

(76) Inventors: Chien-Pin Chen, Tainan County (TW); Chiu-Shun Lin, Tainan County (TW)

Correspondence Address: NORTH AMERICA INTELLECTUAL PROPERTY CORPORATION, P.O. BOX 506, MERRIFIELD, VA, 22116, US

(21) Appl. No.: 12/702,222

(22) Filed: Feb. 8, 2010

Related U.S. Application Data
(60) Provisional application No. 61/170,663, filed on Apr. 20, 2009.

(51) Int. Cl. H01L 23/498; H01L 23/28

(52) U.S. Cl. 257/659; 257/737; 257/E23.06; 257/E23.116

(57) ABSTRACT

A semiconductor device includes a semiconductor chip, a plurality of bumps and at least one electrically conductive component. The semiconductor chip includes an active area having electronic circuits formed therein and a plurality of pads. The plurality of bumps is placed on the semiconductor chip, wherein a location where at least one of the bumps is located on the semiconductor chip does not overlap a location where a specific pad of the pads is located on the semiconductor chip. The electrically conductive component connects a top surface of at least the bump and the specific pad.

### CROSS REFERENCE TO RELATED APPLICATIONS

This application claims the benefit of U.S. Provisional Application No. 61/170,663, filed on Apr. 20, 2009 and included herein by reference.

### BACKGROUND OF THE INVENTION

1. Field of the Invention

The present invention relates to a semiconductor device, and more particularly, to a packaged semiconductor device having at least one bump that does not overlap a specific pad or directly contact the specific pad.

2. Description of the Prior Art

Please refer to FIG. 1, which is a diagram of a conventional packaged semiconductor device 100. The conventional semiconductor device 100 includes a semiconductor chip 101 having an active area 102 full of active and passive electronic circuits and some pads 104 placed surrounding the active area 102, and some bumps 106 directly placed upon the pads 104 for external connection. The pads 104 are placed surrounding the active area 102 because the pressure from the bumps 106 may damage the active electronic circuits within the active area 102.

Please refer to FIG. 2 in conjunction with FIG. 1. FIG. 2 is a diagram of the semiconductor chip 101 shown in FIG. 1 mounted on a substrate 202 utilizing a Chip-On-Glass (COG) technology. As shown in the figure, the semiconductor chip 101 of the semiconductor device 100 occupies an area near the edge due to the inherent chip area of the semiconductor chip 101, leaving the rest of the area on the substrate 202 as a display area. To maximize an area of the display area, it is necessary to reduce the area occupied by the semiconductor chip 101 (i.e., the semiconductor device 100).

### SUMMARY OF THE INVENTION

In order to utilize the display area with more efficiency, the present invention provides a semiconductor device architecture with reduced chip area.

According to one embodiment of the present invention, an exemplary semiconductor device is provided. The semiconductor device includes a semiconductor chip, a plurality of bumps and at least one electrically conductive component. The semiconductor chip includes an active area having electronic circuits formed therein and a plurality of pads. The plurality of bumps is placed on the semiconductor chip, wherein a location where at least one of the bumps is located on the semiconductor chip does not overlap a location where a specific pad of the pads is located on the semiconductor chip. The electrically conductive component connects a top surface of at least the bump and the specific pad.

According to another embodiment of the present invention, an exemplary semiconductor device is also provided. The semiconductor device includes a semiconductor chip, a plurality of bumps and an electrically conductive component. The semiconductor chip includes an active area having electronic circuits formed therein and a plurality of pads. The bumps are placed on the semiconductor chip, wherein at least one of the bumps does not have direct contact with a specific pad of the pads. The electrically conductive component connects a top surface of at least the bump and the specific pad.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a conventional packaged semiconductor device.

FIG. 2 is a diagram of the semiconductor chip shown in FIG. 1 mounted on a substrate utilizing a Chip-On-Glass technology.

FIG. 3 is a semiconductor device according to an embodiment of the present invention.

FIG. 4 is a cross-section view along line 4-4′ of the semiconductor device in FIG. 3 according to an embodiment of the present invention.

FIG. 5 is a diagram of the semiconductor chip shown in FIG. 3 mounted on a substrate utilizing a Chip-On-Glass technology according to an embodiment of the present invention.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

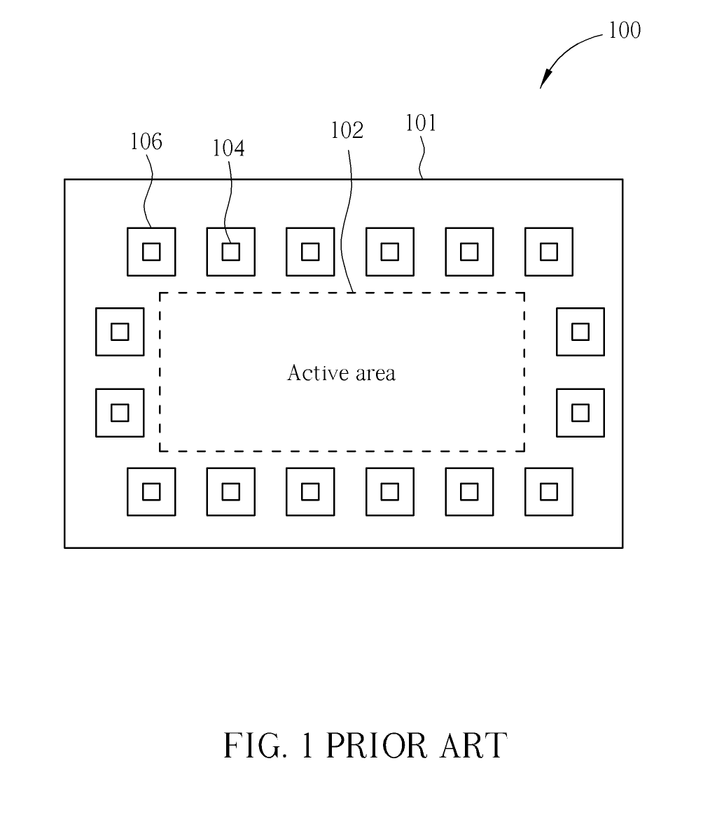

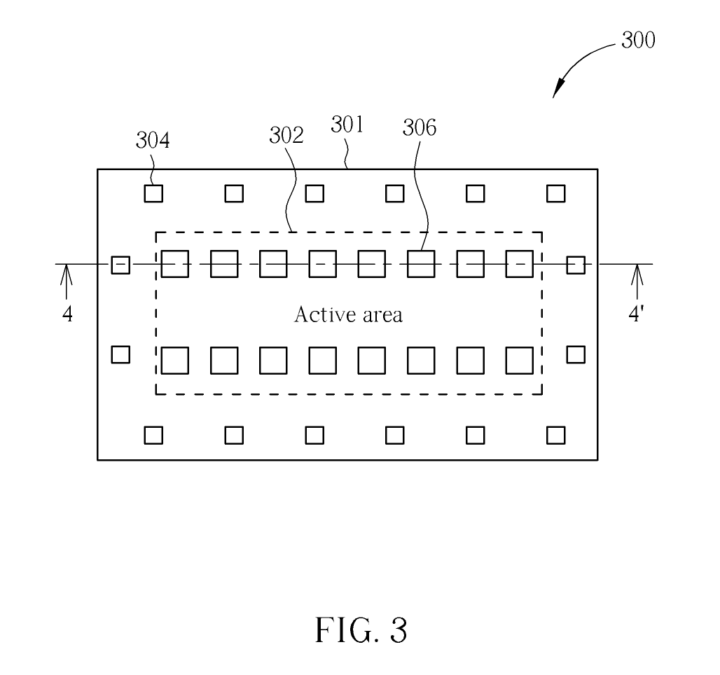

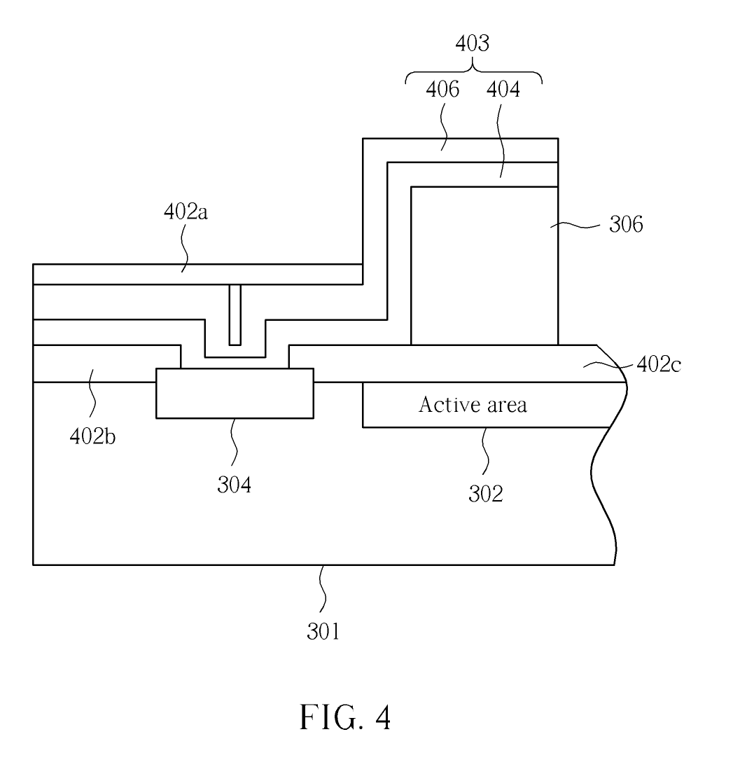

Please refer to FIG. 3, which shows a semiconductor device 300 according to an embodiment of the present invention. In this exemplary embodiment, the semiconductor device 300 includes, but is not limited to, a semiconductor chip 301 which includes an active area 302 having electronic circuits formed therein and a plurality of pads 304, a plurality of bumps 306 placed on the semiconductor chip 301, and an electrically conductive component 403 (not shown in FIG. 3, but shown in FIG. 4) connecting a top surface of each bump 306 and a corresponding pad 304. To further illustrate the semiconductor device 300 in FIG. 3 in detail, please refer to FIG. 4, which is a cross-section view along line 4-4′ of the semiconductor device 300 shown in FIG. 3. For clarity and simplicity, only part of the semiconductor device 300 is illustrated in FIG. 4. As shown in FIG. 4, protection layers 402b and 402c are distributed upon the semiconductor chip 301 except for the top surface of the pad 304. A sputtered layer 404, for example, which is made using titanium compounds as sputtering targets and serves as part of the electronically conducting component 403, is fabricated upon the semiconductor chip 301 to connect the top surface of the pad 304 and the top surface of the bump 306 which is made of an elastic material, e.g., polyimide (PI). In this way, the bump 306 is not necessarily required to be directly placed onto the pad 304 for electrical connection. Furthermore, since the bump 306 is made of PI, the bump 306 can be placed on the active area 302 to save chip area without damaging the functionality of the semiconductor chip 301. In addition, an electronically conductive layer 406, e.g., a metal layer made of gold (an Au layer), is further fabricated upon the sputtered layer to serve as another part of the electronically conducting component 403, thereby improving conductivity without significantly increasing costs. However, it should be noted that the electronically conductive layer 406 is optional, and may be omitted in an alternative design of the present invention. As shown in FIG. 4, another protection layer 402a is fabricated on the electronically conductive layer 403 except for the electrically conductive layer portion on the top surface of the bump 306. Compared with the semiconductor chip 101 in FIG. 1, it can be seen that the semiconductor chip 301 has a smaller total area, and a reduction in cost can thereby be achieved.

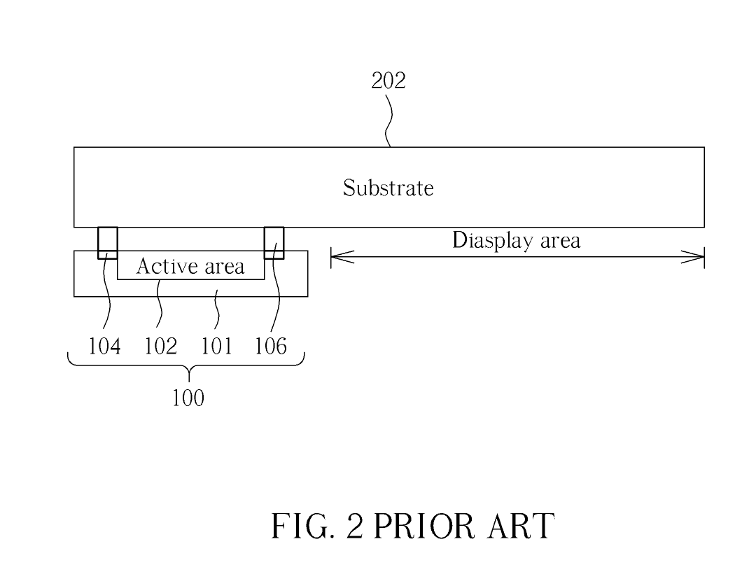

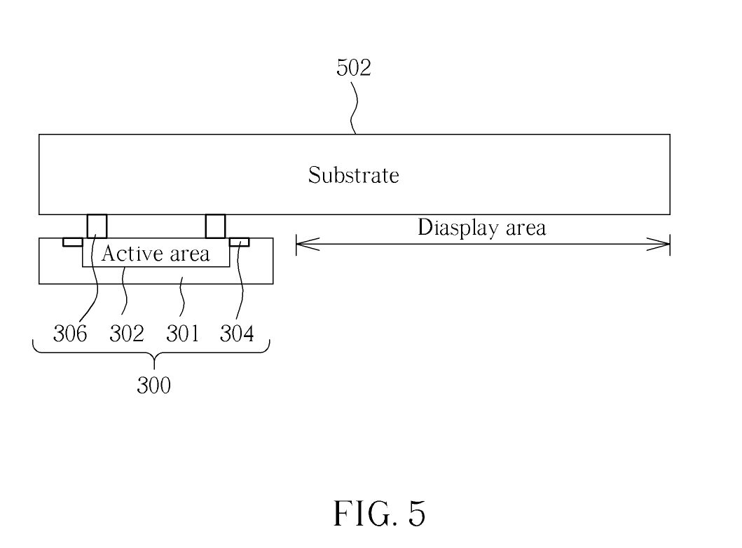

FIG. 5 is a diagram of the semiconductor chip 301 shown in FIG. 3 mounted on a substrate 502 with the COG technology. Compared with the semiconductor chip 101 shown in FIG. 2, the semiconductor chip 301 occupies a smaller area and the area of the display area is thereby increased. In addition, since the bump 306 is made of elastic material, a height of the bump 306 can remain the same when COG technology is utilized to attach the semiconductor chip 301 onto the substrate 502 via the bumps 306.

Please note that the aforementioned embodiment is only for illustrative purposes, and is not supposed to be a limitation to the scope of the present invention. For example, the material of the bump is not limited to PI only, and any other elastic material can also be utilized; moreover, the material of the sputtered layer is also not limited to titanium compounds only. These variations of the design still fall within the scope of the present invention.

As is clearly shown in FIG. 3˜FIG. 5, a location where at least one of the bumps 306 is located on the semiconductor chip 301 does not overlap a location where a specific pad of the pads 304 is located on the semiconductor chip 301; in other words, at least one of the bumps 306 does not have direct contact with a specific pad of the pads 304. In this way, the chip area of the semiconductor chip can be effectively reduced.

To summarize, in accordance with exemplary embodiments of the present invention, a semiconductor device not only saves a chip area but also maximizes a display area. A performance of an apparatus utilizing the semiconductor device can therefore be greatly improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a semiconductor chip, comprising an active area having electronic circuits formed therein and a plurality of pads;
a plurality of bumps, placed on the semiconductor chip, wherein a location where at least one of the bumps is located on the semiconductor chip does not overlap a location where a specific pad of the pads is located on the semiconductor chip; and
at least an electrically conductive component, connecting a top surface of at least the bump and the specific pad.

2. The semiconductor device of claim 1, wherein the bump is located directly above the active area.

3. The semiconductor device of claim 2, wherein the bump is made of an elastic material.

4. The semiconductor device of claim 3, wherein the elastic material is polyimide.

5. The semiconductor device of claim 1, wherein the electrically conductive component comprises a sputtered layer formed on the bump and the specific pad, and the sputtered layer is made of an electrically conductive material.

6. The semiconductor device of claim 5, wherein the electrically conductive component further comprises an electrically conductive layer formed on the sputtered layer.

7. The semiconductor device of claim 1, wherein the semiconductor device further comprises an insulating protection layer on the electrically conductive component except for the electrically conductive component on the top surface of the bump.

8. A semiconductor device, comprising:
a semiconductor chip, comprising an active area having electronic circuits formed therein and a plurality of pads;
a plurality of bumps, placed on the semiconductor chip, wherein at least one of the bumps does not have a direct contact with a specific pad of the pads; and
an electrically conductive component, connecting a top surface of at least the bump and the specific pad.

9. The semiconductor device of claim 8, wherein the bump is located directly above the active area.

10. The semiconductor device of claim 9, wherein the bump is made of an elastic material.

11. The semiconductor device of claim 10, wherein the elastic material is polyimide.

12. The semiconductor device of claim 8, wherein the electrically conductive component comprises a sputtered layer formed on the bump and the specific pad, and the sputtered layer is made of an electrically conductive material.

13. The semiconductor device of claim 12, wherein the electrically conductive component further comprises an electrically conductive layer formed on the sputtered layer.

14. The semiconductor device of claim 8, wherein the semiconductor device further comprises an insulating protection layer on the electrically conductive component except for the electrically conductive component on the top surface of the bump.
